(19) United States
(12) Patent Application Publication
(10) Pub. No.: US 2023/0335809 A1
(43) Pub. Date: Oct. 19, 2023

(54) CHARGING METHOD, ELECTRONIC APPARATUS, AND STORAGE MEDIUM

(71) Applicant: NINGDE AMPEREX TECHNOLOGY LIMITED, Ningde City (CN)

(72) Inventors: Shan Zhu, Ningde City (CN); Ting Guan, Ningde City (CN); Fei Wu, Ningde City (CN); Hongming Yu, Ningde City (CN)

(73) Assignee: NINGDE AMPEREX TECHNOLOGY LIMITED, Ningde City (CN)

(21) Appl. No.: 18/211,963

(22) Filed: Jun. 20, 2023

Related U.S. Application Data
(63) Continuation of application No. PCT/CN2020/137783, filed on Dec. 18, 2020.

(51) Int. Cl. H01M 10/44; H02J 7/00

(52) U.S. Cl. CPC H01M 10/44; H02J 7/0048; H02J 7/00714; H02J 7/007182

(57) ABSTRACT

A battery charging method is provided, including: constant-current charging the battery with a first charge current I₁ to a first voltage U₁ and constant-voltage charging the battery with the first voltage U₁ to a first charge cut-off current I₁′ (S1); constant-current charging the battery with the first charge current I₁ to a second voltage U₂, where U₂ is a limited charge voltage of the battery, and U₂>U₁ (S2); and constant-current charging the battery with a second charge current I₂ to a third voltage U₃ and constant-voltage charging the battery with the third voltage U₃ to a second charge cut-off current I₂′, where U₃>U₂, I₂<I₁, and I₁′≤I₂′ (S3). An electronic apparatus and a medium are provided, which can shorten the time of a battery being at high voltage, thus alleviating capacity decay of the battery during charge-discharge cycles.

### CROSS REFERENCES TO RELATED APPLICATIONS

The present application is a continuation application of PCT/CN2020/137783, filed on Dec. 18, 2020, the disclosure of which is hereby incorporated by reference in its entirety.

### TECHNICAL FIELD

This application relates to the field of battery technologies, and in particular, to a charging method, an electronic apparatus, and a storage medium.

### BACKGROUND

In a lithium-ion battery system, internal materials (such as cathode and anode materials and electrolyte) are important parts. During charge-discharge cycles of a battery, the internal materials are consumed by chemical or electrochemical reactions, thus affecting performance of the battery in capacity, rate, and the like. Both the high voltage and duration of high voltage during battery charging affect the chemical or electrochemical reactions in the battery. Existing charging methods such as multi-step charging and ultra-fast charging can improve the battery performance to some extent, but the improvement is limited. For example, the multi-step charging method can shorten the time of the battery being at high voltage. However, the charge rate of the battery continuously decreases, and there is no significant reduction in either the overall charging time or the time of the battery being at high voltage, so that the battery performance is not significantly improved. For another example, the ultra-fast charging method can significantly shorten the charging time, but due to absence of step-by-step charging, the time of the battery being at high voltage is still long, and the improvement in overall performance is still not significant.

### SUMMARY

In view of this, it is necessary to provide a battery charging method, an electronic apparatus, and a storage medium, so as to meet a requirement for fully charging a battery.

An embodiment of this application provides a battery charging method. The method includes: constant-current charging a battery with a first charge current I₁ to a first voltage U₁ and constant-voltage charging the battery with the first voltage U₁ to a first charge cut-off current I₁′; constant-current charging the battery with the first charge current I₁ to a second voltage U₂; and constant-current charging the battery with a second charge current I₂ to a third voltage U₃ and constant-voltage charging the battery with the third voltage U₃ to a second charge cut-off current I₂′; where U₂ is a limited charge voltage of the battery, U₂>U₁, U₃>U₂, I₂<I₁, and I₁′≤I₂′.

According to some embodiments of this application, the method further includes determining the first voltage U₁. The step of determining the first voltage U₁ includes: determining a phase change potential V_{c} of a cathode material in the battery; obtaining a state of charge of the battery at the phase change potential and determining a corresponding anode potential Vₐ; and obtaining a voltage U_{cv} of the battery based on the phase change potential V_{c} and the anode potential Vₐ, where U_{cv}=V_{c}−Vₐ, and U₁=U_{cv}.

According to some embodiments of this application, the method further includes determining the first charge current I₁. The step of determining the first charge current I₁ includes: after the battery has been discharged to a fully discharged state, charging the battery with a first preset current at a preset temperature to a fully charged state; discharging the battery with a second preset current to the fully discharged state; after cyclically performing the charging the battery with the first preset current to the fully charged state and discharging the battery with the second preset current to the fully discharged state for a preset number of times, determining whether lithium precipitation occurs on an anode plate of the battery; and if lithium precipitation occurs on the anode plate of the battery, determining that the first preset current is the first charge current I₁ of the battery at the preset temperature.

According to some embodiments of this application, the step of determining the first charge current I₁ further includes: if no lithium precipitation occurs on the anode plate of the battery, adjusting the first preset current; charging the battery with the adjusted first preset current at the preset temperature to the fully charged state; discharging the battery with the second preset current to the fully discharged state; after cyclically performing the charging the battery with the adjusted first preset current to the fully charged state and discharging the battery with the second preset current to the fully discharged state for a preset number of times, determining whether lithium precipitation occurs on the anode plate of the battery; and if lithium precipitation occurs on the anode plate of the battery, determining that the adjusted first preset current is the first charge current I₁ of the battery at the preset temperature.

According to some embodiments of this application, U₂<U₃≤U₂+500 mV.

According to some embodiments of this application, 0.5I₁<I₂<I₁.

According to some embodiments of this application, 0.1 C<I₁′<0.6 C, where C is a charge/discharge rate.

According to some embodiments of this application, 0.1 C<I₂′<0.6 C.

According to some embodiments of this application, the method further includes setting values of the first voltage U₁, the second voltage U₂, the third voltage U₃, the first charge current I₁, the second charge current I₂, the first charge cut-off current I₁′, and the second charge cut-off current I₂′.

An embodiment of this application provides an electronic apparatus. The electronic apparatus includes a battery and a processor, where the processor is configured to execute the foregoing charging method to charge the battery.

An embodiment of this application provides a storage medium storing at least one computer instruction, where the instruction is loaded by a processor to execute the foregoing charging method.

In some embodiments of this application, before the voltage of the battery reaches the first voltage, the constant current plus constant voltage charging method is used for charging the battery as much as possible, and then the high-rate constant current charging plus overcharging method is used in the subsequent charging process. This can not only ensure fast charging of the battery, but also shorten the time of the battery being at high voltage, thus alleviating capacity decay of the battery during charge-discharge cycles.

### BRIEF DESCRIPTION OF DRAWINGS

FIG. 1 is a schematic diagram of an electronic apparatus according to an embodiment of this application.

FIG. 2 is a flowchart of a charging method according to an embodiment of this application.

FIG. 3 is a schematic diagram of current change over time during charge according to an embodiment of this application.

FIG. 4 is a schematic diagram of voltage change over time during charge according to an embodiment of this application.

FIG. 5 is a schematic diagram of comparison between battery capacity decays in charging and discharging a battery using a conventional method and the charging method of this application.

FIG. 6 is a diagram of functional modules of a charging system according to an embodiment of this application.

### REFERENCE SIGNS OF MAIN COMPONENTS

Electronic apparatus 1
Charging system 10
Memory 11
Processor 12
Battery 13
First charging module 101
Second charging module 102
Third charging module 103

### DETAILED DESCRIPTION

The following clearly and completely describes technical solutions in some embodiments of this application with reference to the accompanying drawings in some embodiments of this application. Apparently, the described embodiments are some but not all embodiments of this application.

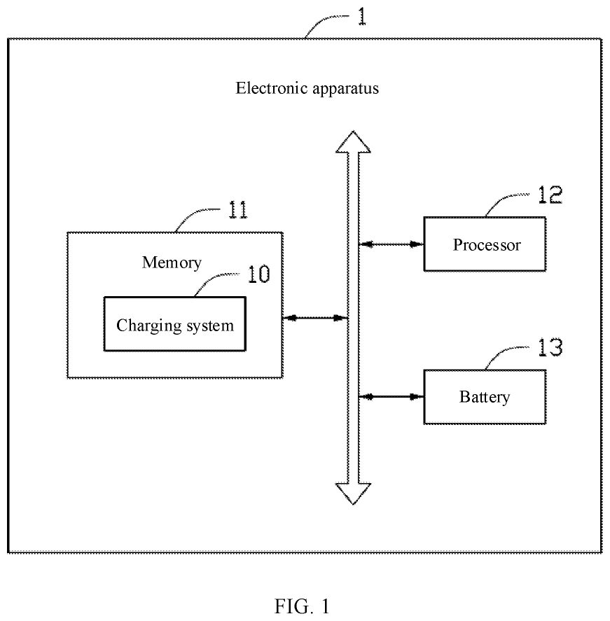

Referring to FIG. 1, FIG. 1 is a schematic diagram of an electronic apparatus according to an embodiment of this application. Referring to FIG. 1, a charging system 10 runs in an electronic apparatus 1. The electronic apparatus 1 includes but is not limited to a memory 11, at least one processor 12, and a battery 13, where the memory 11, the at least one processor 12, and the battery 13 may be connected to one another through a bus, or may be directly connected.

In an embodiment, the battery 13 is a rechargeable battery for supplying electric energy to the electronic apparatus 1. For example, the battery 13 may be a lithium-ion battery, a lithium polymer battery, a lithium iron phosphate battery, or the like. The battery 13 includes at least one battery cell (battery cell) and is appropriate to use a recyclable recharging manner. The battery 13 is logically connected to the processor 12 through a power management system, so as to implement functions such as charging, discharging, and power consumption management through the power management system.

It should be noted that FIG. 1 is only an example for description of the electronic apparatus 1. In other embodiments, the electronic apparatus 1 may instead include more or fewer components or have a different configuration of components. The electronic apparatus 1 may be an electric motorcycle, an electric bicycle, an electric vehicle, a mobile phone, a tablet computer, a personal digital assistant, a personal computer, or any other appropriate rechargeable devices.

Although not shown, the electronic apparatus 1 may further include a wireless fidelity (Wireless Fidelity, Wi-Fi) unit, a Bluetooth unit, a loudspeaker, and other components. Details are not described herein.

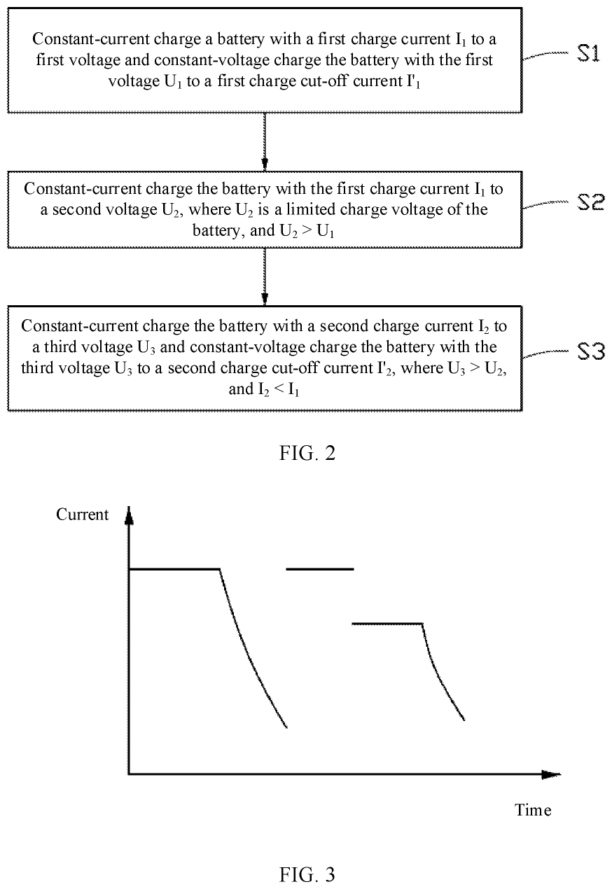

Referring to FIG. 2, FIG. 2 is a flowchart of a battery charging method according to an embodiment of this application. Depending on different demands, the sequence of steps in the flowchart may be changed, and some steps may be omitted. This application proposes a charging method from a perspective of stability of battery materials during charge, so as to shorten the time of a battery being at high voltage and alleviate capacity decay and polarization growth of the battery during charge-discharge cycles. Specifically, the charging method may include the following steps.

Step S1. Constant-current charge a battery with a first charge current I₁ to a first voltage U₁ and constant-voltage charge the battery with the first voltage U₁ to a first charge cut-off current I₁′.

In this embodiment, the constant-current and constant-voltage charging method is used first for charging the battery as much as possible before the voltage of the battery reaches a stable voltage (that is, the first voltage U₁). In this way, charging time of the battery after the voltage has become greater than the stable voltage is shortened.

In this embodiment, the method further includes determining the first charge current I₁. Specifically, the step of determining the first charge current I₁ includes: after the battery has been discharged to a fully discharged state, charging the battery with a first preset current (for example, 1 C) at a preset temperature to a fully charged state; discharging the battery with a second preset current (for example, 0.2 C) to the fully discharged state; after cyclically performing the charging the battery with the first preset current to the fully charged state and discharging the battery with the second preset current to the fully discharged state for a preset number of times (for example, 5 times), determining whether lithium precipitation occurs on an anode plate of the battery; and if lithium precipitation occurs on the anode plate of the battery, determining that the first preset current is the first charge current I₁ of the battery at the preset temperature; or if no lithium precipitation occurs on the anode plate of the battery, adjusting the first preset current (for example, the adjusted first preset current is 1.1 C); charging the battery with the adjusted first preset current at the preset temperature to the fully charged state; discharging the battery with the second preset current to the fully discharged state; after cyclically performing the charging the battery with the adjusted first preset current to the fully charged state and discharging the battery with the second preset current to the fully discharged state for a preset number of times (for example, 5 times), determining whether lithium precipitation occurs on the anode plate of the battery; and if lithium precipitation occurs on the anode plate of the battery, determining that the adjusted first preset current (that is, the current at which lithium precipitation just begins as the charge current increases) is the first charge current I₁ of the battery at the preset temperature.

It should be noted that the first charge currents at different temperatures may also be determined. Specifically, the first charge currents at different temperatures can be obtained by adjusting the preset temperature and performing the same charging process and lithium precipitation status analysis using the above method for determining the first charge current I₁.

In this embodiment, the method further includes determining the first voltage U₁. Specifically, the step of determining the first voltage U₁ includes: determining a phase change potential V_{c} of a cathode material in the battery; obtaining a state of charge of the battery at the phase change potential and determining a corresponding anode potential Vₐ; and obtaining a voltage U_{cv} of the battery based on the phase change potential V_{c} and the anode potential Vₐ, where U_{cv}=V_{c}−Vₐ, and U₁=U_{cv}.

In this embodiment, magnitude of the first charge cut-off current is related to the charging time and charge capacity of the battery. Specifically, to charge as much power as possible before the voltage of the battery reaches a stable voltage to shorten the charging time of the battery, it is necessary to limit the first charge cut-off current I₁′. If the first charge cut-off current is excessively small, it takes longer for the voltage of the battery to reach the stable voltage and excessively little power is charged into the battery. If the first charge cut-off current is excessively large, the purpose of charging as much power as possible before the voltage of the battery reaches the stable voltage cannot be achieved. Therefore, in this application, 0.1 C<I₁′<0.6 C, where C is a charge/discharge rate.

It should be noted that the charge/discharge rate refers to a current required for charging to a rated capacity or discharging the rated capacity within a specified time, and is numerically equal to charge/discharge current/rated capacity of battery. For example, when the rated capacity is 10 Ah and the battery discharges at 2 A, the discharge rate of the battery is 0.2 C; and when the battery discharges at 20 A, the discharge rate of the battery is 2 C. In this embodiment, the fully discharged state means that power in the battery is 0 after the battery is discharged. In another embodiment, the fully discharged state may mean that the battery is discharged to a preset power level.

Step S2. Constant-current charge the battery with the first charge current I₁ to a second voltage U₂, where U₂ is a limited charge voltage of the battery, and U_{z}>U₁.

In this embodiment, after the battery is charged at a constant current and constant voltage to the first voltage U₁, it is necessary to continue charging the battery to the limited charge voltage of the battery (that is, the second voltage U₂), where U₂>U₁. In this way, the high-rate constant current charging plus overcharging method can be used to reduce the time of the battery being at high voltage.

Step S3. Constant-current charge the battery with a second charge current I₂ to a third voltage U₃ and constant-voltage charge the battery with the third voltage U₃ to a second charge cut-off current I₂′, where U₃>U₂, and I₂<I₁.

In this embodiment, after the battery is charged to the limited charge voltage, it is also necessary to charge the battery to the fully charged state. The battery can be charged to the fully charged state by widening the limited charge voltage. To be specific, the limited charge voltage of the battery, the second voltage U₂, is widened to the third voltage U₃, that is, U₃>U₂. However, the third voltage should not be higher than a decomposition potential of electrolyte in a battery cell system of the battery, therefore U₂<U₃≤U_{z}+500 mV. In the case of U₃≤U_{z}+500 mV, no lithium precipitation will occur in the battery. It should be noted that the third voltage U₃ is a voltage of the battery in the fully charged state and satisfies U₂<U₃≤U₂+100 mV in a preferred embodiment.

In this application, after the battery has been charged to the second voltage U₂, the battery is charged at a reduced current so that the voltage of the battery reaches the third voltage U₃. Therefore, the second charge current I₂ is less than the first charge current I₁. Further preferably, U₂<U₃≤U₂+100 mV.

In this embodiment, the second charge current I₂ is a constant charge current for overcharging the battery. It is necessary to consider the second charge current I₂ and an overcharge voltage comprehensively to ensure that when the second charge current I₂ is used for overvoltage charge, no lithium precipitation occurs at the anode and no overdelithiation occurs at the cathode of the battery. Therefore, the second charge current needs to satisfy 0.5I₁<I₂<I₁.

In addition, it should be noted that both the method for determining whether lithium precipitation occurs at the anode of the battery and the method for determining that no overdelithiation occurs at the cathode of the battery belong to the prior art. Details are not described herein.

In this embodiment, the second charge cut-off current I₂′ is mainly influenced by the charge capacity. The charge capacity can be guaranteed using the constant voltage cut-off current, and the charging time can also be controlled. The second charge cut-off current satisfies 0.1 C<I₂′<0.6 C, and I₁′<I₂′.

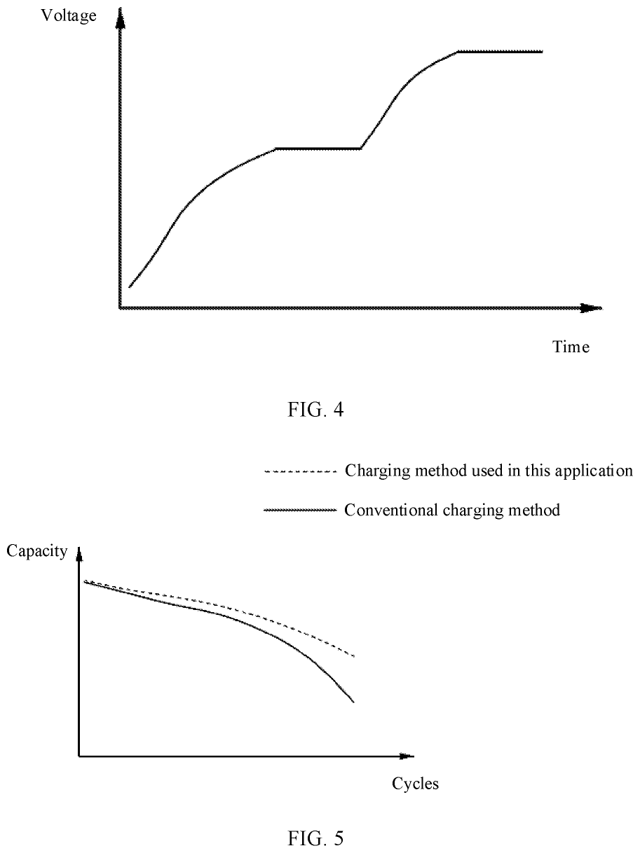

In this application, the battery is constant-current charged with the first charge current I₁ to the first voltage U₁ and the battery is constant-voltage charged with the first voltage U₁ to the first charge cut-off current I₁′; the battery is constant-current charged with the first charge current I₁ to the second voltage U₂; and the battery is constant-current charged with the second charge current I₂ to the third voltage U₃ and the battery is constant-voltage charged with the third voltage U₃ to the second charge cut-off current I₂′. In the entire charging process, the current change over time is shown in FIG. 3, and the voltage change over time is shown in FIG. 4. In addition, the constant-current and constant-voltage charging before the voltage of the battery reaches the first voltage may be one-step constant-current and constant-voltage charging or multi-step constant-current and constant-voltage charging. In the case of multi-step charging, the charge voltage is gradually increased and the charge current is gradually reduced. Refer to the existing multi-step charging method.

In this application, the charging method further includes setting values of the first voltage U₁, the second voltage U₂, the third voltage U₃, the first charge current I₁, the second charge current I₂, the first charge cut-off current I₁′, and the second charge cut-off current I₂′.

The charging method provided in this embodiment of this application can greatly reduce the time of the battery being at high voltage and significantly suppress the side reactions of electrode materials, thereby improving the battery performance during cycling.

To make the objectives, technical solutions, and technical effects of this application clearer, the following further describes this application in detail with reference to the accompanying drawings and examples. It should be understood that the examples provided in this specification are merely intended to interpret this application, but not intended to limit this application. This application is not limited to the examples provided in this specification.

### Comparative Example 1

A conventional charging method (such as a constant-current and constant-voltage charging method) was used to charge the battery. In this example, the ambient temperature was 45° C. during the battery charge process.
(1) The battery was constant-current charged with a charge current of 1.5 C to 4.4 V.
(2) The battery was constant-voltage charged with a constant charge voltage of 4.4 V to a cut-off current of 0.05 C.
(3) The battery was left standing for 5 min.
(4) The battery was constant-current discharged with a discharge current of 0.5 C to a discharge cut-off voltage of 3.0 V.
(5) The battery was left standing for 5 min.
(6) The above steps (1) to (5) were cycled 500 times, that is, the battery was subjected to 500 charge-discharge cycles.

### Example 1

The battery charging method provided in this application was used to charge the battery. In this example, the ambient temperature was 45° C. during the battery charge process.
(1) The battery was constant-current charged with a charge current of 1.5 C to 4.1 V.
(2) The battery was constant-voltage charged with a constant charge voltage of 4.1 V to a cut-off current of 0.2 C.
(3) The battery was constant-current charged with a charge current of 1.5 C to 4.4V.
(4) The battery was constant-current charged with a charge current of 1 C to 4.5 V.
(5) The battery was constant-voltage charged with a constant charge voltage of 4.5 V to a cut-off current of 0.4 C.
(6) The battery was left standing for 5 min.
(7) The battery was constant-current discharged with a discharge current of 0.5 C to a discharge cut-off voltage of 3.0 V.
(8) The battery was left standing for 5 min.
(9) The above steps (1) to (8) were cycled 500 times, that is, the battery was subjected to 500 charge-discharge cycles.

Referring to FIG. 5, it can be learned that when the conventional charging method is used to charge and discharge the battery, the capacity of the battery decays more as the number of cycles increases; and when the charging method provided in this application is used to charge and discharge the battery, the capacity of the battery decays less as the number of cycles increases. It can be learned that the charging method provided in this application can alleviate capacity decay of the battery during charge-discharge cycles.

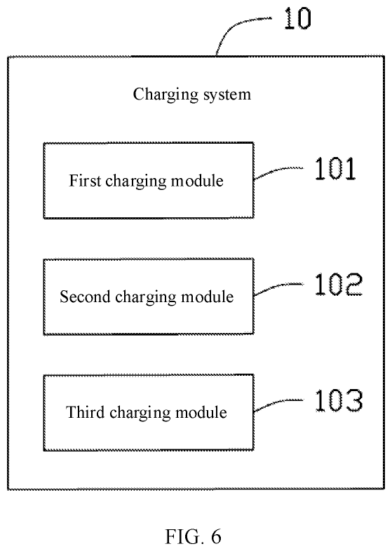

Referring to FIG. 6, in this embodiment, the charging system 10 may be divided into one or more modules, where the one or more modules may be stored in the processor 12, and the processor 12 executes the charging method in some embodiments of this application. The one or more modules may be a series of computer program instruction segments capable of completing particular functions, where the instruction segments are used to describe a process of execution by the charging system 10 in the electronic apparatus 1. For example, the charging system 10 may be divided into a first charging module 101, a second charging module 102, and a third charging module 103 in FIG. 6.

The first charging module 101 is configured to constant-current charge the battery with a first charge current I₁ to a first voltage U₁ and constant-voltage charge the battery with the first voltage U₁ to a first charge cut-off current 14. The second charging module 102 is configured to constant-current charge the battery with the first charge current I₁ to a second voltage U₂, where U_{z} is a limited charge voltage of the battery, and U₂>U₁. The third charging module 103 is configured to constant-current charge the battery with a second charge current I₂ to a third voltage U₃ and constant-voltage charge the battery with the third voltage U₃ to a second charge cut-off current I₂′, where U₃>U₂, I₂<I₁, and I₁′≤I₂′.

With the charging system 10, the time of the battery being at high voltage can be shortened, thus alleviating capacity decay and polarization growth of the battery during charge-discharge cycles. For specific content, reference may be made to the foregoing embodiments of the battery charging method. Details are not described herein again.

In one embodiment, the processor 12 may be a central processing unit (Central Processing Unit, CPU) or another general-purpose processor, a digital signal processor (Digital Signal Processor, DSP), an application-specific integrated circuit (Application Specific Integrated Circuit, ASIC), a field-programmable gate array (Field-Programmable Gate Array, FPGA) or another programmable logic device, a discrete gate or transistor logic device, a discrete hardware component, or the like. The general-purpose processor may be a microprocessor, or the processor 12 may be any other conventional processor or the like.

If implemented in a form of software functional units and sold or used as separate products, the modules in the charging system 10 may be stored in a computer-readable storage medium. Based on such an understanding, in this application, all or some of the processes in the method of the above embodiments may also be accomplished by a computer program instructing relevant hardware. The computer program may be stored in a computer readable storage medium, and the computer program, when executed by a processor, can implement the steps of the above method embodiments. The computer program includes computer program code. The computer program code may be in the form of source code, object code, or an executable file or in some intermediate forms or the like. The computer-readable medium may include any entity or means capable of carrying the computer program code, a recording medium, a USB flash drive, a removable hard disk, a magnetic disk, an optical disc, a computer memory, a read-only memory (ROM, Read-Only Memory), a random access memory (RAM, Random Access Memory), or the like.

It can be understood that the module division described above is a logical functional division, and other division manners may be used in actual implementation. In addition, function modules in an embodiment of this application may be integrated into one processing unit, or each of the modules may exist alone physically, or two or more modules may be integrated into one unit. The integrated module may be implemented either in the form of hardware or in the form of hardware plus software function modules.

The one or more modules may alternatively be stored in the memory and executed by the processor 12. The memory 11 may be an internal storage device of the electronic apparatus 1, that is, a storage device built in the electronic apparatus 1. In other embodiments, the memory 11 may alternatively be an external storage device of the electronic apparatus 1, that is, a storage device externally connected to the electronic apparatus 1.

In some embodiments, the memory 11 is configured to: store program code and various data, for example, program code of the charging system 10 installed on the electronic apparatus 1; and implement high-speed automatic access to programs or data during running of the electronic apparatus 1.

The memory 11 may include a random access memory, and may also include a non-volatile memory, for example, a hard disk, an internal memory, a plug-in hard disk, a smart media card (Smart Media Card, SMC), a secure digital (Secure Digital, SD) card, a flash card (Flash Card), at least one disk storage device, a flash memory device, or other non-volatile solid-state storage devices.

It is apparent to those skilled in the art that this application is not limited to the details of the above illustrative embodiments and that this application can be implemented in other specific forms without departing from the spirit or essential features of this application. Therefore, from whatever point of view, the above embodiments of this application should be regarded as illustrative and non-limiting, and the scope of this application is defined by the appended claims but not the above descriptions, and thus all variations falling within the meaning and scope of equivalent elements of the claims of this application are intended to be incorporated into this application.

What is claimed is:

1. A method for charging a battery, wherein the method comprises:
constant-current charging the battery with a first charge current I₁ to a first voltage U₁ and constant-voltage charging the battery with the first voltage U₁ to a first charge cut-off current I₁′;
constant-current charging the battery with the first charge current I₁ to a second voltage U₂, wherein U₂ is a limited charge voltage of the battery, and U₂>U₁; and
constant-current charging the battery with a second charge current I₂ to a third voltage U₃ and constant-voltage charging the battery with the third voltage U₃ to a second charge cut-off current I₂′, wherein U₃>U₂, I₂<I₁, and I₁′<I₂′.

2. The method according to claim 1, wherein the method further comprises determining the first voltage U₁, and the step of determining the first voltage U₁ comprises:
determining a phase change potential V_{c} of a cathode material in the battery;
obtaining a state of charge of the battery at the phase change potential and determining a corresponding anode potential Vₐ; and
obtaining a voltage U_{cv} of the battery based on the phase change potential V_{c} and the anode potential Vₐ, wherein U_{cv}=V_{c}−Vₐ, and U₁=U_{cv}.

3. The method according to claim 1, wherein the method further comprises determining the first charge current I₁, and the step of determining the first charge current I₁ comprises:
after the battery has been discharged to a fully discharged state, charging the battery with a first preset current at a preset temperature to a fully charged state;
discharging the battery with a second preset current to the fully discharged state;
after cyclically performing the charging the battery with the first preset current to the fully charged state and discharging the battery with the second preset current to the fully discharged state for a preset number of times, determining whether lithium precipitation occurs on an anode plate of the battery; and
if lithium precipitation occurs on the anode plate of the battery, determining that the first preset current is the first charge current I₁ of the battery at the preset temperature.

4. The method according to claim 3, wherein the step of determining the first charge current I₁ further comprises:
if no lithium precipitation occurs on the anode plate of the battery, adjusting the first preset current;
charging the battery with the adjusted first preset current at the preset temperature to the fully charged state;
discharging the battery with the second preset current to the fully discharged state;
after cyclically performing the charging the battery with the adjusted first preset current to the fully charged state and discharging the battery with the second preset current to the fully discharged state for a preset number of times, determining whether lithium precipitation occurs on the anode plate of the battery; and
if lithium precipitation occurs on the anode plate of the battery, determining that the adjusted first preset current is the first charge current I₁ of the battery at the preset temperature.

5. The method according to claim 1, wherein U₂<U₃≤U₂+500 mV.

6. The method according to claim 1, wherein 0.5I₁<I₂<I₁.

7. The method according to claim 1, wherein 0.1 C<I₁′<0.6 C, C being a charge/discharge rate.

8. The method according to claim 7, wherein 0.1 C<I₂′<0.6 C.

9. An electronic apparatus, wherein the electronic apparatus comprises:
a battery; and
a processor configured to execute a charging method,
wherein the method comprises:
constant-current charging a battery with a first charge current I₁ to a first voltage U₁ and constant-voltage charging the battery with the first voltage U₁ to a first charge cut-off current I₁′;
constant-current charging the battery with the first charge current I₁ to a second voltage U₂, wherein U₂ is a limited charge voltage of the battery, and U₂>U₁; and
constant-current charging the battery with a second charge current I₂ to a third voltage U₃ and constant-voltage charging the battery with the third voltage U₃ to a second charge cut-off current I₂′, wherein U₃>U₂, I₂<I₁, and I₁′≤I₂′.

10. A storage medium storing at least one computer instruction, wherein the instruction is loaded by a processor, configured to execute a charging method, wherein the method comprises:
constant-current charging a battery with a first charge current I₁ to a first voltage U₁ and constant-voltage charging the battery with the first voltage U₁ to a first charge cut-off current I₁′;
constant-current charging the battery with the first charge current I₁ to a second voltage U₂, wherein U₂ is a limited charge voltage of the battery, and U₂>U₁; and
constant-current charging the battery with a second charge current I₂ to a third voltage U₃ and constant-voltage charging the battery with the third voltage U₃ to a second charge cut-off current I₂′, wherein U₃>U₂, I₂<I₁, and I₁′≤I₂′.
